(19) United States
(12) Patent Application Publication
(10) Pub. No.: US 2026/0178814 A1
(43) Pub. Date: Jun. 25, 2026

(54) COMPUTING DEVICE AND VERIFICATION METHOD FOR PERFORMING VERIFICATION ON LAYOUT OF INTEGRATED CIRCUITS

(71) Applicant: Samsung Electronics Co., Ltd., Suwon-si (KR)

(72) Inventors: Jae-Young So, Suwon-si (KR); Jimin Yeo, Suwon-si (KR); Yong-Seok Lee, Suwon-si (KR); Yunseong Lee, Suwon-si (KR); Heejae Lim, Suwon-si (KR); Min-Ho Jung, Suwon-si (KR)

(21) Appl. No.: 19/421,727

(22) Filed: Dec. 16, 2025

(30) Foreign Application Priority Data
Dec. 20, 2024 (KR) 10-2024-0192626

(51) Int. Cl. G06F 30/398; G06F 30/392

(52) U.S. Cl. CPC G06F 30/398; G06F 30/392

(57) ABSTRACT

A verification method for a layout of an integrated circuit performed by a computer device includes comparing a first netlist corresponding to a schematic diagram of the integrated circuit and a second netlist corresponding to a first layout of the integrated circuit, generating a second layout by applying a pre-input retarget rule to the first layout in response to determining that the first netlist and the second netlist correspond to each other, generating a first text file, including coordinate data for each of layers included in the first layout, from the first layout, generating a second text file, including coordinate data for each of layers included in the second layout, from the second layout, and outputting verification information indicating whether a difference between the first layout and the second layout corresponds to pre-stored feature data, based on the first text file and the second text file.

### CROSS-REFERENCE TO RELATED APPLICATION(S)

This U.S. non-provisional application claims priority under 35 U.S.C. § 119 to Korean Patent Application No. 10-2024-0192626, filed on Dec. 20, 2024, in the Korean Intellectual Property Office, the disclosure of which is herein incorporated by reference in its entirety.

### BACKGROUND

The present disclosure relates to a computing device and a verification method for verifying a layout of integrated circuits.

A designer may design an integrated circuit by setting a schematic diagram (or schematic data) of the integrated circuit to allow the integrated circuit to perform a desired function. The schematic diagram of the integrated circuit may include various elements such as a transistor, a resistor, or a diode, and may define connection relationships between the elements.

The designer may generate a layout of an integrated circuit, implemented by stacking a plurality of layers, based on a schematic diagram of the integrated circuit. The layout of the integrated circuit may include data on the plurality of layers manufactured using a semiconductor process.

As part of the verification process to reduce defects in designed integrated circuits, a layout-versus-schematic (LVS) technique is employed to compare and verify a schematic diagrams and layout data before the integrated circuits enter actual manufacturing processes for mass production.

### SUMMARY

In general, the present disclosure is directed toward a verification method to improve the reliability of a layout of an integrated circuit.

According to some implementations, the present disclosure is directed to a verification method for a layout of an integrated circuit performed by a computer device that includes comparing a first netlist corresponding to a schematic diagram of the integrated circuit and a second netlist corresponding to a first layout of the integrated circuit, generating a second layout by applying a pre-input retarget rule to the first layout in response to determining that the first netlist and the second netlist correspond to each other, generating a first text file, including coordinate data for each of layers included in the first layout, from the first layout, generating a second text file, including coordinate data for each of layers included in the second layout, from the second layout, and outputting verification information indicating whether a difference between the first layout and the second layout corresponds to pre-stored feature data, based on the first text file and the second text file.

According to some implementations, the present disclosure is directed to a computing system includes at least one processor and a memory configured to store instructions causing at least one processor to perform a verification method for an integrated circuit when the instructions are executed by the at least one processor. The verification method may include comparing a first netlist corresponding to a schematic diagram of the integrated circuit and a second netlist corresponding to a first layout of the integrated circuit, generating a second layout by applying a pre-input retarget rule to the first layout in response to determining that the first netlist and the second netlist correspond to each other, generating a first text file, comprising coordinate data for each of layers included in the first layout, from the first layout, generating a second text file, comprising coordinate data for each of layers included in the second layout, from the second layout, and outputting first verification information when a difference between the first layout and the second layout is determined to correspond to pre-stored feature data, based on the first text file and the second text file.

According to some implementations, the present disclosure is directed to a verification method for a layout of integrated circuits performed by a computer device that includes obtaining a first netlist corresponding to a schematic diagram of the integrated circuit, obtaining a second netlist corresponding to a first layout of the integrated circuit, comparing the first netlist and the second netlist to determine whether elements included in the schematic diagram correspond to elements included in the first layout, generating a second layout by applying a retarget rule to the first layout in response to determining that the elements included in the schematic diagram correspond to the elements included in the first layout, generating a first text file corresponding to the first layout, generating a second text file corresponding to the second layout, and comparing the first text file and the second text file to output verification information indicating whether a difference between the first layout and the second layout corresponds to pre-stored feature data.

### BRIEF DESCRIPTION OF DRAWINGS

Example implementations will be more clearly understood from the following detailed description, taken in conjunction with the accompanying drawings.

FIG. 1 is a block diagram of an example of a computing device according to some implementations.

FIG. 2 is a block diagram illustrating an example of an operation in which a computing device verifies an integrated circuit according to some implementations.

FIG. 3A is a schematic diagram of an example of an integrated circuit according to some implementations.

FIG. 3B is a diagram illustrating an example of a first layout of an integrated circuit according to some implementations.

FIG. 4 is a diagram illustrating an example configuration to compare a first netlist corresponding to a schematic diagram of an integrated circuit with a second netlist corresponding to a first layout of the integrated circuit according to some implementations.

FIG. 5 is a diagram illustrating an example of a second layout of an integrated circuit according to some implementations.

FIG. 6A is a diagram illustrating an example of at least a portion of a first text file generated from a first layout according to some implementations.

FIG. 6B is a diagram illustrating an example of at least a portion of a second text file generated from a second layout according to some implementations.

FIG. 7 is a diagram illustrating an example of a pre-stored feature data table according to some implementations.

FIG. 8 is a diagram illustrating an example of a configuration to output a display image with at least a portion of a second layer highlighted, when a difference between a first layer and the second layer does not correspond to a second correction value according to some implementations.

FIG. 9 is a diagram illustrating an example of a first layout including a plurality of first via layers according to some implementations.

FIG. 10 is a diagram illustrating an example of a second layout including a second via layer according to some implementations.

FIG. 11 is a flowchart illustrating an example of a verification method for an integrated circuit according to some implementations.

FIG. 12 is a flowchart illustrating an example of a method for outputting different verification information based on a verification result according to some implementations.

FIG. 13 is a flowchart illustrating an example of a verification method for an integrated circuit based on a difference in width between a first layer and a second layer according to some implementations.

FIG. 14 is a flowchart illustrating an example of a verification method for an integrated circuit based on an area difference between via layers of a first layout and a second layout according to some implementations.

FIG. 15 is a block diagram illustrating an example of an integrated circuit and an electronic device including the same according to some implementations.

### DETAILED DESCRIPTION

Hereinafter, example implementations will be described in detail with reference to the accompanying drawings.

The term “first,” “second,” or the like used herein may modify various elements regardless of the order and/or priority thereof, and is used only for distinguishing one element from another element, without limiting example embodiments.

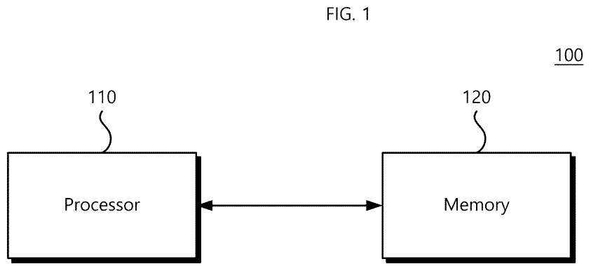

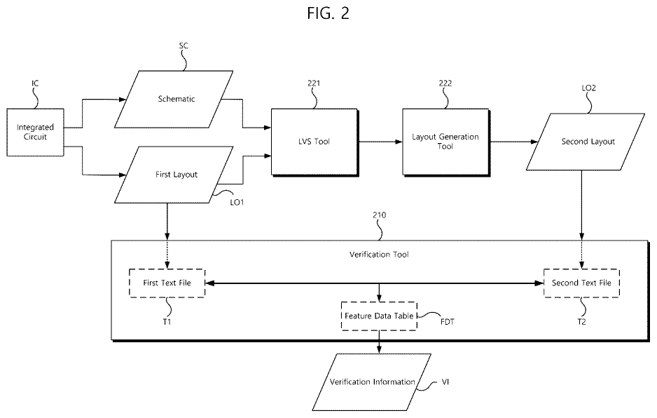

FIG. 1 is a block diagram of an example of a computing system according to some implementations. FIG. 2 is a block diagram illustrating an example of an operation in which a computing system verifies an integrated circuit according to some implementations.

Referring to FIGS. 1 and 2, a computing system 100 may verify a layout (for example, a second layout LO2) generated from an integrated circuit IC. For example, the computing system 100 may output verification information VI as a result obtained by verifying the layout generated from the integrated circuit IC.

Referring to FIG. 1, the computing system 100 may include a processor 110 and a memory 120.

The computing system 100 may include a memory 120 configured to store data.

For example, the memory 120 may store programs and/or data for controlling the operation of the computing device 100.

To this end, the memory 120 may include at least one of a random access memory (RAM), a read-only memory (ROM), a flash memory, a hard disk, a solid state drive (SSD), a card-type memory (for example, an SD or XD memory), a magnetic memory, a magnetic disk, or an optical disk. In addition, the computing system 100 according to one or more embodiments may operate in connection with a web storage performing a storage function of the memory 120 over the Internet.

In addition, the computing system 100 may include a processor 110 controlling the overall operation of the computing system 100.

The processor 110 may execute, for example, software or programs stored in the memory 120 to control at least one other component of the computing device 100 and perform various data processing or computations. The processor 110 may include a central processing unit or a microprocessor and may control the overall operation of the computing system 100. Accordingly, operations performed by the computing system 100 may be understood as being performed under the control of the processor 110. Throughout the present disclosure, reference to “processor” is understood to include “one or more processors.”

According to some implementations, the processor 110 may compare a schematic diagram SC of an integrated circuit IC with a first layout LO1. For example, the processor 110 may determine whether the first layout LO1 and the schematic diagram SC of the integrated circuit IC have corresponding features.

For example, the features may include parameters (for example, length, width, or the like) of each of the devices included in the schematic diagram SC and the first layout LO1 and connection relationships between the devices, but the present disclosure is not limited thereto.

According to some implementations, the processor 110 may obtain a netlist from each of the schematic diagram SC and the first layout LO1. For example, the processor 110 may obtain a first netlist corresponding to the schematic diagram SC of the integrated circuit IC. In addition, the processor 110 may obtain a second netlist corresponding to the first layout LO1 of the integrated circuit IC.

The first netlist may include parameters of each of the devices included in the schematic diagram SC and the connection relationships between the devices. Similarly, the second netlist may include parameters of each of the devices included in the first layout LO1 and the connection relationships between the devices.

Furthermore, the processor 110 may compare the first netlist and the second netlist. For example, the processor 110 may compare the first netlist and the second netlist to determine whether the devices included in the schematic diagram SC and the first layout LO1 have corresponding parameters and connection relationships.

For example, referring to FIG. 2, the processor 110 may input the first netlist and the second netlist to an LVS tool 221. The LVS tool 221 may determine whether the devices included in the schematic diagram SC and the first layout LO1 have corresponding parameters and connection relationships, based on the first netlist and the second netlist.

Furthermore, when the features of the schematic diagram SC and the first layout LO1 correspond to each other, the processor 110 may generate a second layout LO2 from the first layout LO1.

For example, when the devices included in the schematic diagram SC and the first layout LO1 have corresponding parameters and connection relationships, the processor 110 may generate the second layout LO2 from the first layout LO1.

The processor 110 may generate a second layout LO2 based on the first layout LO1 and a pre-input retarget rule. For example, the processor 110 may generate the second layout LO2 by applying the retarget rule to the first layout LO1.

For example, the processor 110 may input the first layout LO1 in a layout generation tool 222. The layout generation tool 222 may generate the second layout LO2 based on the first layout LO1 and the pre-input retarget rule.

The retarget rule may include correction values and/or correction rules applied to each of the plurality of devices or layers included in the first layout LO1 when the second layout LO2 is generated from the first layout LO1.

For example, the retarget rule may include a correction value applied to the width of a layer included in the first layout LO1 when the second layout LO2 is generated.

For example, the retarget rule may include a correction rule for generating a single via layer from a plurality of via layers included in the first layout LO1 when the second layout LO2 is generated.

However, the correction values and correction rules included in the retarget rule are not limited to the above examples and may be understood to include various correction values and correction rules that may be applied to each of the devices or layers included in the first layout LO1.

In addition, for example, the retarget rule may be pre-input and stored in the memory 120.

For example, when the schematic diagram SC and the first layout LO1 correspond to each other, the processor 110 may generate the second layout LO2 based on the first layout LO1 and the pre-input retarget rule.

For example, the first layout LO1 may be referred to as a graphic data system (GDS) layout, and the second layout LO2 may be referred to as an annotated geometry format (AGF) layout.

In addition, the processor 110 may verify the second layout LO2 (or the integrated circuit IC) by comparing the first layout LO1 with the second layout LO2.

For example, the processor 110 may compare parameters (for example, width) of corresponding layers in the first layout LO1 and the second layout LO2.

For example, the processor 110 may compare a first layer included in the first layout LO1 with a second layer corresponding to the first layer in the second layout LO2. For example, the processor 110 may compare parameters (for example, width) of the first layer and the second layer.

According to some implementations, the processor 110 may input the first layout LO1 and the second layout LO2 to a verification tool 210. The verification tool 210 may convert the first layout LO1 into a first text file T1 and the second layout LO2 into a second text file T2.

According to some implementations, the verification tool 210 (or the processor 110) may generate the first text file T1 from the first layout LO1. For example, the verification tool 210 may generate the first text file T1 including coordinates of each of the layers included in the first layout LO1. For example, the first text file T1 may include coordinate values corresponding to vertices of the first layer included in the first layout LO1. For example, the first text file T1 may be referred to as ASCII code corresponding to the first layout LO1.

In addition, the verification tool 210 (or the processor 110) may generate the second text file T2 from the second layout LO2. For example, the verification tool 210 may generate the second text file T2 including coordinates of each layer included in the second layout LO2. For example, the second text file T2 may include coordinate values corresponding to vertices of the second layer included in the second layout LO2. For example, the second text file T2 may be referred to as ASCII code corresponding to the second layout LO2.

Furthermore, the verification tool 210 may output verification information VI based on a comparison result between the first text file T1 and the second text file T2 and a feature data table FDT.

The feature data table FDT may be referred to as a look-up table pre-stored in the memory 120.

The feature data table FDT according to one or more embodiments may include feature data on a difference between the first layout LO1 and the second layout LO2. For example, the feature data table FDT may include feature data indicating a difference in width between a first layer of the first layout LO1 and a second layer of the second layout LO2. For example, the feature data table FDT may include a correction value set for the width of the first layer to generate the second layer.

The verification tool 210 may compare the first text file T1 and the second text file T2 to identify differences between layers included in the first layout LO1 and the second layout LO2.

For example, the verification tool 210 may identify the width of the first layer from the coordinates of the first layer included in the first text file T1. Similarly, the verification tool 210 may identify the width of the second layer from the coordinates of the second layer included in the second text file T2.

In addition, the verification tool 210 may obtain a difference between the width of the first layer and the width of the second layer.

In addition, the verification tool 210 may determine whether the identified difference corresponds to the feature data stored in the feature data table FDT.

For example, the verification tool 210 may determine whether the difference between the width of the first layer and the width of the second layer corresponds to a correction value stored in the feature data table FDT in correspondence with the width of the first layer.

In addition, the verification tool 210 (or the processor 110) may output verification information VI based on the difference between the first layout LO1 and the second layout LO2 identified from the first text file T1 and the second text file T2, and the feature data table FDT.

For example, the verification tool 210 may output first verification information when the difference between the first layout LO1 and the second layout LO2 correspond to the feature data in the feature data table FDT.

The first verification information may include information indicating that the second layout LO2 has been generated to have a bias based on the feature data included in the feature data table FDT from the first layout LO1. For example, the first verification information may include information indicating that the second layout LO2 has passed verification based on the feature data table FDT.

For example, the verification tool 210 may output second verification information when at least a portion of the difference between the first layout LO1 and the second layout LO2 do not correspond to the feature data in the feature data table FDT.

The second verification information may include information indicating that at least some layers of the second layout LO2 have been generated to have a bias, different from the feature data included in the feature data table FDT, from the first layout LO1. For example, the second verification information may include information related to layers in the second layout LO2 that failed to pass verification based on the feature data table FDT.

According to some implementations, operations performed by the LVS tool 221, the layout generation tool 222, and the verification tool 210 may be understood as being performed by the processor 110.

Referring to the above-described configurations, the processor 110 may generate the second layout LO2 by applying a retarget rule to the first layout LO1 of the integrated circuit IC.

In addition, the processor 110 may convert each of the first layout LO1 and the second layout LO2 into text files T1 and T2. In addition, the processor 110 may identify differences between layers included in the first layout LO1 and the second layout LO2 based on the coordinates included in the text files T1 and T2.

Accordingly, the computing system 100 may reduce the time required for verifying a layout (for example, the second layout LO2) generated from the integrated circuit IC.

Moreover, the processor 110 may output verification information VI based on whether the differences between layers included in the first layout LO1 and the second layout LO2 correspond to pre-stored feature data.

The verification information VI may include information indicating whether each of the layers included in the second layout LO2 has been generated to have a bias corresponding to the feature data included in the feature data table FDT from the layers included in the first layout LO1.

As a result, the computing system 100 may improve the reliability of a layout (for example, the second layout LO2) generated from the integrated circuit IC.

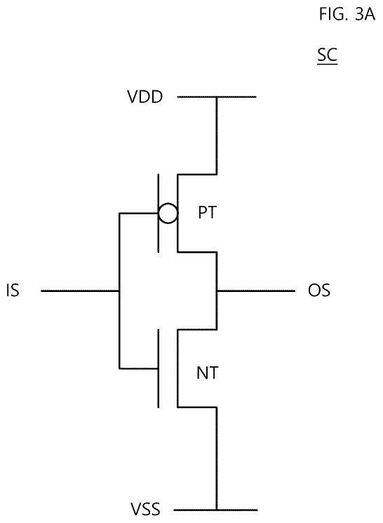

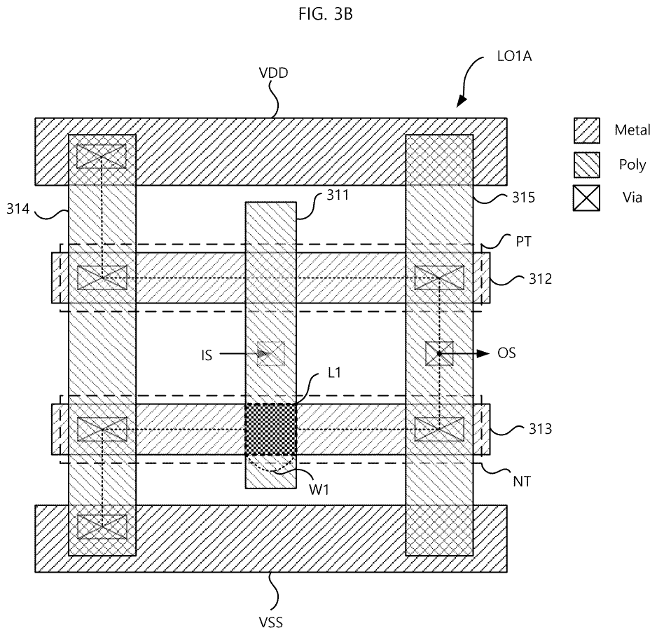

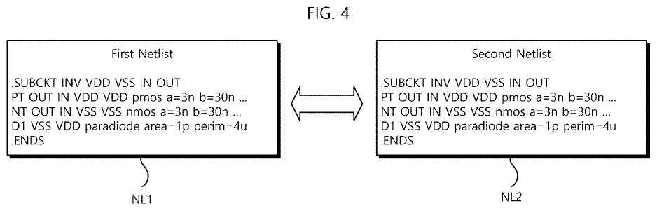

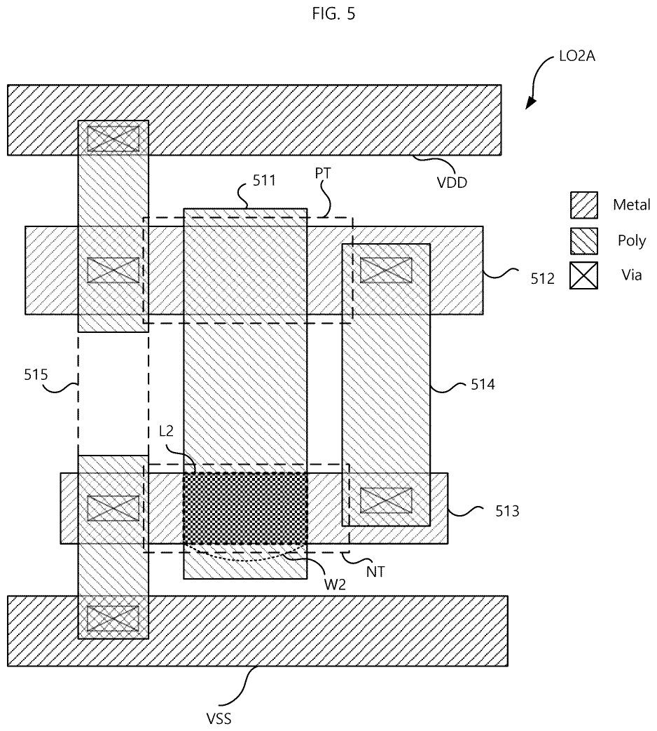

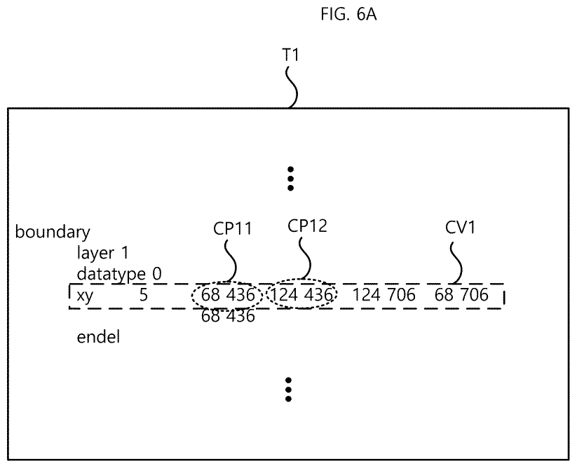

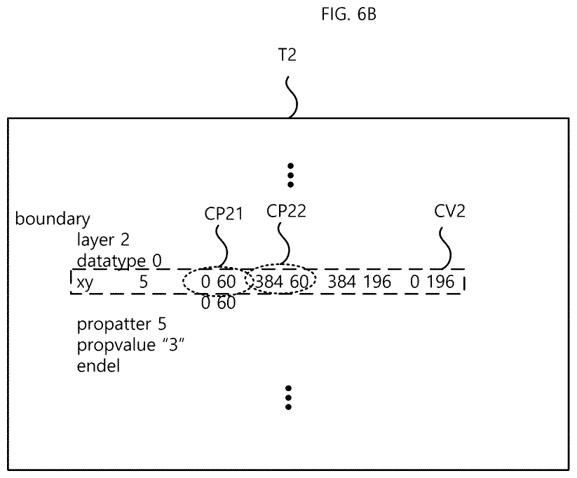

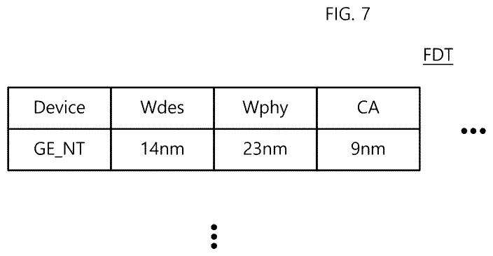

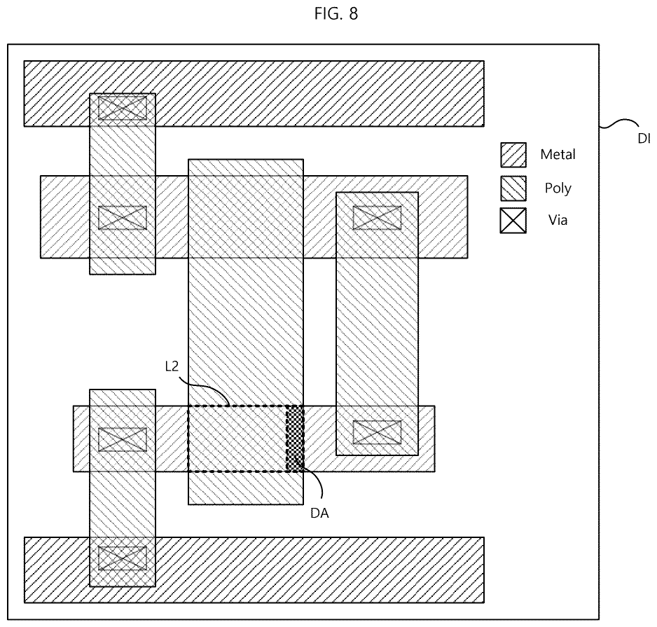

FIG. 3A is a schematic diagram of an example of an integrated circuit according to some implementations. FIG. 3B is a diagram illustrating an example of a first layout of an integrated circuit according to some implementations. FIG. 4 is a diagram illustrating an example of a configuration to compare a first netlist corresponding to a schematic diagram of an integrated circuit with a second netlist corresponding to a first layout of the integrated circuit according to some implementations. FIG. 5 is a diagram illustrating an example of a second layout of an integrated circuit according to some implementations. FIG. 6A is a diagram illustrating an example of at least a portion of a first text file generated from a first layout according to some implementations. FIG. 6B is a diagram illustrating an example of at least a portion of a second text file generated from a second layout according to some implementations. FIG. 7 is a diagram illustrating an example of a pre-stored feature data table according to some implementations. FIG. 8 is a diagram illustrating an example of a configuration to output a display image with at least a portion of a second layer highlighted, when a difference between a first layer and the second layer does not correspond to a second correction value according to some implementations.

Referring to FIGS. 3A to 8, a computing system 100 may verify a layout (for example, a second layout LO2A) generated from an integrated circuit IC. The computing system 100 may be referred to as the computing system 100 illustrated in FIG. 1.

For example, the computing system 100 may verify the second layout LO2A based on whether a difference between the second layout LO2A and a first layout LO1A corresponds to pre-stored feature data.

The first layout LO1A and the second layout LO2A illustrated in FIGS. 3b and 5 may be understood as examples of the first layout LO1 and the second layout LO2 illustrated in FIG. 2, respectively. Accordingly, the same or substantially the same components are represented by the same reference numerals, and redundant descriptions will be omitted to avoid repetition.

Referring to FIGS. 3A and 3B, an integrated circuit IC may be referred to as an inverter. For example, the integrated circuit IC may be referred to as an inverter inverting an input signal IS and outputting the inverted version of the input signal IS as an output signal OS.

The schematic diagram SC and the first layout LO1A according to one or more embodiments may include a PMOS transistor PT and an NMOS transistor NT.

For example, the schematic diagram SC and the first layout LO1A may include a PMOS transistor PT connected to a power supply voltage VDD. In addition, the schematic diagram SC and the first layout LO1A may include an NMOS transistor NT connected between the PMOS transistor PT and a ground voltage VSS.

Referring to FIG. 3B, the first layout LO1A may include a plurality of first patterns 311 to 315 connected to each other through vias. The first layout LO1A may be understood as an example of the first layout LO1 illustrated in FIG. 2.

A region of a first pattern 311, overlapping a second pattern 312, may be referred to as a gate electrode of the PMOS transistor PT. Regions of the second pattern 312, disposed on opposite sides from the region overlapping the first pattern 311, may be referred to as source-drain electrodes of the PMOS transistor PT.

A region of the first pattern 311, overlapping a third pattern 313, may be referred to as a gate electrode of the NMOS transistor NT. Regions of the third pattern 313, disposed on opposite sides from the region overlapping the first pattern 311, may be referred to as source-drain electrodes of the NMOS transistor NT.

Referring to FIGS. 3A to 4, the processor 110 (or the computing system 100) may compare the schematic diagram SC and the first layout LO1A. For example, the processor 110 may determine whether the first layout LO1A and the schematic diagram SC have corresponding features.

For example, the features may include parameters (for example, length and width) of each of the devices included in the schematic diagram SC and the first layout LO1A and connection relationships between the devices, but the present disclosure is not limited thereto.

For example, the processor 110 may obtain a netlist from each of the schematic diagram SC and the first layout LO1A. The processor 110 may obtain a first netlist NL1 corresponding to the schematic diagram SC. In addition, the processor 110 may obtain a second netlist NL2 corresponding to the first layout LO1A.

The first netlist NL1 may include parameters of each device included in the schematic diagram SC and/or the connection relationships between the devices. For example, the first netlist NL1 may include length “a” and width “b” of each of the PMOS transistor PT and the NMOS transistor NT included in the schematic diagram SC.

In addition, the second netlist NL2 may include parameters of each device included in the first layout LO1A and/or the connection relationships between the devices. For example, the second netlist NL2 may include length “a” and width “b” of each of the PMOS transistor PT and the NMOS transistor NT included in the first layout LO1A.

In addition, the processor 110 may compare the first netlist NL1 and the second netlist NL2. For example, the processor 110 may compare the first netlist NL1 and the second netlist NL2 to determine whether the devices included in the schematic diagram SC and the first layout LO1A have corresponding parameters and connection relationships.

For example, the processor 110 may compare the first netlist NL1 and the second netlist NL2 to determine whether the lengths “a” and widths “b” of the PMOS transistors PT included in the schematic diagram SC and the first layout LO1A are the same.

Referring to FIGS. 3B and 5, the processor 110 may generate a second layout LO2A from the first layout LO1A when the features of the schematic diagram SC and the first layout LO1 correspond to each other.

For example, the processor 110 may generate the second layout LO2A from the first layout LO1A when the parameters and connection relationships of the transistors PT and NT included in the schematic diagram SC and the first layout LO1A correspond to each other.

Referring to FIG. 5, the second layout LO2A may include a plurality of second patterns 511 to 515 corresponding to the plurality of first patterns 311 to 315 of the first layout LO1A.

For example, the second layout LO2A may include a first pattern 511 corresponding to the first pattern 311 included in the first layout LO1A. In addition, for example, the second layout LO2A may include a fourth pattern 514 corresponding to the fourth pattern 314 included in the first layout LO1A.

According to some implementations, the processor 110 may generate the second layout LO2A based on the first layout LO1A and a pre-input retarget rule. For example, the processor 110 may generate the second layout LO2A by applying the retarget rule to the first layout LO1A.

The retarget rule may include correction values and/or correction rules applied to each of the plurality of devices or layers included in the first layout LO1A when the second layout LO2A is generated.

For example, the retarget rule may include a first correction value applied to the first width W1 of a first layer L1 included in the first layout LO1A when the second layout LO2A is generated. The first layer L1 may be understood as a region of the first pattern 311 overlapping the third pattern 313.

Accordingly, the processor 110 may generate a second layout LO2A including a second layer L2 having a second width W2, which is equal to the sum of the first width W1 and the first correction value, based on the retarget rule including the first correction value. The second layer L2 may be understood as a region of the first pattern 511 overlapping the third pattern 513. In addition, the second layer L2 may be referred to as a layer included in the second layout LO2A corresponding to the first layer L1 included in the first layout LO1A.

For example, the retarget rule may include a first correction rule for generating a second layout LO2A including a second layer L2 having a width, which is equal to the sum of the first width W1 of the first layer L1 and the first correction value, from the first layout LO1A.

In addition, the processor 110 may verify the second layout LO2A by comparing the first layout LO1A and the second layout LO2A.

For example, the processor 110 may compare parameters (for example, width) of corresponding layers in the first layout LO1A and the second layout LO2A.

For example, referring to FIGS. 3B and 5, the processor 110 may compare a first width W1 of the first layer L1 with a second width W2 of the second layer L2.

Referring to FIGS. 6A and 6B, the processor 110 may convert the first layout LO1A into a first text file T1 and the second layout LO2A into a second text file T2.

According to some implementations, the processor 110 may generate the first text file T1 from the first layout LOIA. The first text file T1 may include first coordinate data CV1 corresponding to vertices of the first layer L1 included in the first layout LO1A.

In addition, the processor 110 may generate the second text file T2 from the second layout LO2A. The second text file T2 may include second coordinate data CV2 corresponding to vertices of the second layer L2 included in the second layout LO2A.

Referring to FIGS. 6A to 7, the processor 110 may output verification information VI based on a comparison result between the first text file T1 and the second text file T2 and a feature data table FDT. The feature data table FDT may be referred to as a look-up table pre-stored in a storage device (for example, the memory 120 of FIG. 1).

For example, the processor 110 may compare the first coordinate data CV1 and the second coordinate data CV2 to identify a difference between a first width W1 of the first layer L1 and a second width W2 of the second layer L2.

The processor 110 may identify the first width W1 of the first layer L1 from the first coordinate data CV1.

For example, the processor 110 may identify the first width W1 based on a distance between a (1-1)-th a first coordinate CP11 and a second coordinate CP12 corresponding to different vertices of the first layer L1 in the first coordinate data CV1.

For example, when the first coordinate CP11 is (68, 436) and the second coordinate CP12 is (124, 436), the processor 110 may identify the first width W1 of the first layer L1 based on the distance (for example, “56”) between the (1-1)-th coordinate CP11 and the (1-2)-th coordinate CP12.

For example, the processor 110 may identify the first width W1 of the first layer L1 as 14 nm based on the distance between the first coordinate CP11 and the second coordinate CP12.

In addition, the processor 110 may identify the second width W2 of the second layer L2 from the second coordinate data CV2.

For example, the processor 110 may identify the second width W2 based on a distance between a first coordinate CP21 and a second coordinate CP22 corresponding to different vertices of the second layer L2 in the second coordinate data CV2.

For example, when the first coordinate CP21 is (0, 60) and the second coordinate CP22 is (384, 60), the processor 110 may identify the second width W2 of the second layer L2 based on the distance (for example, “384”) between the first coordinate CP21 and the second coordinate CP22.

For example, the processor 110 may identify the second width W2 of the second layer L2 as 23 nm based on the distance between the first coordinate CP21 and the second coordinate CP22.

Furthermore, the processor 110 may obtain the difference between the first width W1 of the first layer L1 and the second width W2 of the second layer L2. For example, the processor 110 may determine that the difference between the first width W1 and the second width W2 is 9 nm.

In addition, the processor 110 may determine whether the identified difference corresponds to feature data stored in the feature data table FDT.

Referring to FIG. 7, the feature data table FDT may include a design width Wdes, a physical width Wphy, and a second correction value CA corresponding to each device.

The design width Wdes may be understood as a width of each layer included in the integrated circuit IC in the first layout LO1A. The physical width Wphy may be understood as a width of each layer included in the integrated circuit IC in the second layout LO2A. The second correction value CA may be understood as a difference between the width of each layer in the first layout LO1A and the width in the second layout LO2A.

Accordingly, the processor 110 may determine whether the difference between the first layout LO1A and the second layout LO2A corresponds to the second correction value CA stored for the corresponding regions in the first layout LO1A and the second layout LO2A.

For example, the processor 110 may determine whether the difference between the first width W1 and the second width W2 matches the second correction value CA for a layer corresponding to the gate electrode GE_NT of the NMOS transistor NT in the feature data table FDT.

In addition, the processor 110 may output verification information VI based on a difference between the first layout LO1A and the second layout LO2A, identified from the first text file T1 and the second text file T2, and the feature data table FDT.

According to some implementations, the processor 110 may output first verification information when the difference between the first layout LO1A and the second layout LO2A corresponds to the feature data in the feature data table FDT.

For example, the processor 110 may output first verification information when the difference between the first width W1 and the second width W2 is determined to be 9 nm and the second correction value CA for the layer corresponding to the gate electrode GE_NT of the NMOS transistor NT in the feature data table FDT is 9 nm.

The first verification information may include information indicating that the second layout LO2A has been generated to have a bias based on the feature data included in the feature data table FDT from the first layout LO1A. For example, the first verification information may include information indicating that the second layout LO2A has passed verification based on the feature data table FDT.

According to some implementations, the processor 110 may output second verification information when at least a portion of the difference between the first layout LO1A and the second layout LO2A does not correspond to the feature data in the feature data table FDT.

For example, the processor 110 may output second verification information when the difference between the first width W1 of the first layer L1 and the second width W2 of the second layer L2 does not correspond to the second correction value CA for the layer corresponding to the gate electrode GE_NT of the NMOS transistor NT in the feature data table FDT.

The second verification information may include information indicating that at least a portion of layers of the second layout LO2A has been generated to have a bias, different from the feature data included in the feature data table FDT, from the first layout LO1A. For example, the second verification information may include information related to layers in the second layout LO2A that failed to pass verification based on the feature data table FDT.

Referring to FIG. 8, the second verification information may include a display image DI highlighted within a difference area DA of the second layer L2 on the second layout LO2A, where the difference area DA corresponds to the difference between the first correction value and the second correction value CA.

For example, when the second correction value CA is determined to be 9 nm and the first correction value is determined to be 10 nm, the second verification information may include a display image DI highlighted within the difference area DA corresponding to 1 nm within the second layer L2. The processor 110 according to one or more embodiments may output the display image DI through a display device connected to the computing system 100.

Referring to the above-described configurations, the processor 110 may generate the second layout LO2A by applying a retarget rule to the first layout LO1A of the integrated circuit IC.

In addition, the processor 110 may convert each of the first layout LO1A and the second layout LO2A into text files T1 and T2. In addition, the processor 110 may identify differences between parameters (for example, width) of each of the layers L1 and L2 included in the first layout LO1A and the second layout LO2A based on the coordinates included in the text files T1 and T2.

Thus, the computing system 100 may reduce the time required for verifying a layout (for example, the second layout LO2A) generated from the integrated circuit IC.

Moreover, the processor 110 may output verification information IV based on whether the differences between the layers L1 and L2 included in the first layout LO1A and the second layout LO2A correspond to pre-stored feature data.

The verification information IV may include information indicating whether each layer (for example, the second layer L2) included in the second layout LO2A has been generated to have a bias corresponding to the feature data included in the feature data table FDT from the layers (for example, the first layer L1) included in the first layout LO1A.

As a result, the computing system 100 \ may improve the reliability of a layout (for example, the second layout LO2A) generated from the integrated circuit IC.

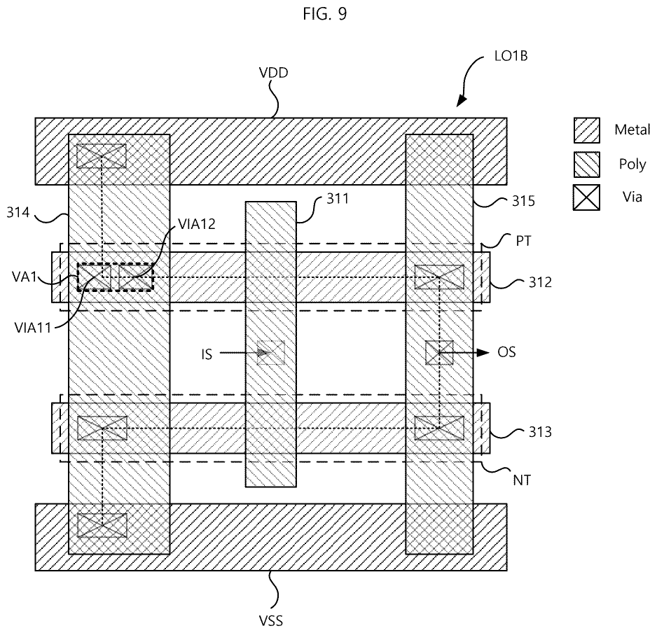

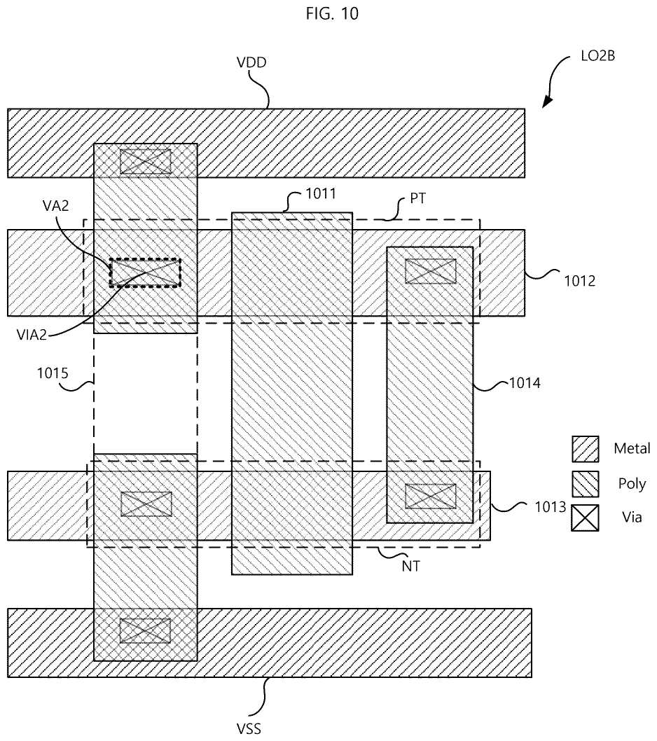

FIG. 9 is a diagram illustrating an example of a first layout including a plurality of first via layers according to some implementations. FIG. 10 is a diagram illustrating an example of a second layout including a second via layer according to some implementations.

Referring to FIGS. 9 and 10, the computing system 100 (or the processor 110) may generate a second layout LO2B from a first layout LO1B based on a retarget rule for via layers.

The first layout LO1B and the second layout LO2B illustrated in FIGS. 9 and 10 may be understood as examples of the first layout LO1 and the second layout LO2 illustrated in FIG. 2, respectively. Accordingly, the same or substantially the same components are represented by the same reference numerals, and redundant descriptions will be omitted to avoid repetition.

Referring to FIG. 9, the first layout LO1B of an integrated circuit IC may include at least two or more first via layers VIA11 and VIA12 disposed near each other. For example, the first layout LO1B may include a first via layer VIA11 and a second via layer VIA12 spaced at a distance less than or equal to a threshold distance.

In addition, each of the first via layer VIA11 and the second via layer VIA12 may have a smaller area than a predetermined threshold value. For example, each of the first via layer VIA11 and the second via layer VIA12 may have an area of 616 nm², which is smaller than or equal to a threshold value of 620 nm².

In addition, the first via region VA1 including the first via layer VIA11 and the second via layer VIA12 may have an area greater than the sum of areas of the first via layer VIA11 and the second via layer VIA12 (for example, 1232 nm²).

Referring to FIGS. 9 and 10, the processor 110 may generate the second layout LO2B from the first layout LO1B.

Referring to FIG. 10, the second layout LO2B may include a plurality of second patterns 1011 to 1015 corresponding to the plurality of first patterns 311 to 315 of the first layout LO1B.

For example, the second layout LO2B may include a first pattern 1011 corresponding to a first pattern 311 included in the first layout LO1B. In addition, for example, the second layout LO2B may include a second pattern 1014 corresponding to a second pattern 314 included in the first layout LO1B.

According to some implementations, the processor 110 may generate the second layout LO2B based on the first layout LO1B and a pre-input retarget rule.

The retarget rule may include correction values and/or correction rules applied to each of the plurality of layers included in the first layout LOIB when the second layout LO2B is generated.

For example, the retarget rule may include a second correction rule for generating a second layout LO2B including a second via layer VIA2 having an area equal to the sum of areas of the first via layers VIA11 and VIA12 from the first layout LO1B. The second via layer VIA2 may be referred to as a layer including a single via.

Accordingly, the processor 110 may generate a second layout LO2B including a second via layer VIA2 having an area equal to the sum of the areas of the first via layers VIA11 and VIA12 based on the second correction rule.

In addition, the processor 110 may verify the second layout LO2B by comparing the first layout LO1B and the second layout LO2B.

For example, the processor 110 may compare parameters (for example, area) of corresponding layers in the first layout LO1B and the second layout LO2B.

For example, the processor 110 may compare a first area of the first via region VA1 including the first via layers VIA11 and VIA12 and a second area of the second via region VA2 including the second via layer VIA2.

For example, the processor 110 may generate a first text file T1 from the first layout LO1B. The first text file T1 may include coordinate data corresponding to vertices of the first via region VA1 included in the first layout LO1B.

Accordingly, the processor 110 may determine the first area of the first via region VA1 from the coordinate data corresponding to the vertices of the first via region VA1.

In addition, the processor 110 may generate a second text file T2 from the second layout LO2B. The second text file T2 may include coordinate data corresponding to vertices of the second via region VA2 included in the second layout LO2B.

Accordingly, the processor 110 may determine the second area of the second via region VA2 from the coordinate data corresponding to the vertices of the second via region VA2.

In addition, the processor 110 may output verification information VI based on a comparison result between corresponding layers in the first layout LO1B and the second layout LO2B and a feature data table FDT.

For example, the processor 110 may determine a difference between the first area of the first via region VA1 and the second area of the second via region VA2.

In addition, the processor 110 may determine whether the determined difference in area corresponds to feature data stored in the feature data table FDT.

The feature data may include a difference value in area between via layers disposed in corresponding regions of the first layout LO1B and the second layout LO2B.

For example, the feature data table FDT may include an area value (for example, 1240 nm²) of via layers disposed in a region in which the PMOS transistor PT is connected to the power supply voltage VDD in the first layout LO1B. In addition, the feature data table FDT may include an area value (for example, 1232 nm²) of via layers disposed in a region in which the PMOS transistor PT is connected to the power supply voltage VDD in the second layout LO2B. In addition, the feature data table FDT may include a difference value (for example, 8 nm²) in area between the via layers disposed in a region in which the PMOS transistor PT is connected to the power supply voltage VDD in the first layout LO1B and the second layout LO2B.

For example, the processor 110 may determine whether the difference between the first area of the first via region VA1 and the second area of the second via region VA2 matches an area difference value stored in the feature data table FDT corresponding to the via layers.

In addition, the processor 110 may output verification information VI based on the difference between the first layout LO1B and the second layout LO2B, identified from the first text file T1 and the second text file T2, and the feature data table FDT.

According to some implementations, the processor 110 may output first verification information when the difference between the first layout LO1B and the second layout LO2B corresponds to the feature data in the feature data table FDT.

For example, the processor 110 may output first verification information when the difference between a first area of the first via region VA1 and a second area of the second via layer VIA2 corresponds to an area difference value stored for the via layers of the first layout LO1B and the second layout LO2B.

For example, the processor 110 may output first verification information when the first area of the first via region VA1 is “1240 nm²,” the second area of the second via region VA2 is “1232 nm²,” and the difference value stored in the feature data table FDT is “8 nm².”

The first verification information may include information indicating that the second layout LO2B has been generated to have a bias based on the feature data included in the feature data table FDT from the first layout LO1B. For example, the first verification information may include information indicating that the second layout LO2B has passed verification based on the feature data table FDT.

According to some implementations, the processor 110 may output second verification information when at least a portion of the difference between the first layout LO1B and the second layout LO2B do not correspond to the feature data in the feature data table FDT.

For example, the processor 110 may output second verification information when the difference between the first area of the first via region VA1 and the second area of the second via layer VIA2 does not correspond to the area difference value stored for the via layers of the first layout LO1B and the second layout LO2B.

For example, the processor 110 may output second verification information when the first area of the first via region VA1 is “1240 nm²,” the second area of the second via region VA2 is “1239 nm²,” and the difference value stored in the feature data table FDT is “8 nm².”

The second verification information may include information indicating that at least some layers (for example, the second via layer VIA2 of the second layout LO2B) have been generated to have a bias, different from the feature data included in the feature data table FDT, from the first layout LO1B. For example, the second verification information may include information related to layers in the second layout LO2B that failed to pass verification based on the feature data table FDT.

Referring to the above-described configurations, the processor 110 may generate the second layout LO2B by applying a retarget rule to the first layout LO1B of the integrated circuit IC.

In addition, the processor 110 may convert the first layout LO1B and the second layout LO2B into text files T1 and T2, respectively. Furthermore, the processor 110 may identify differences between parameters (for example, area) of each of the via layers VIA11, VIA12, and VIA2 included in the first layout LO1B and the second layout LO2B based on the coordinates included in the text files T1 and T2.

Accordingly, the computing system 100 may reduce the time required for verifying a layout (for example, the second layout LO2B) generated from the integrated circuit IC.

Furthermore, the processor 110 may output verification information IV based on whether the differences between the via layers VIA11, VIA12, VIA2 included in the first layout LO1B and the second layout LO2B correspond to pre-stored feature data. The verification information IV may include information indicating whether each layer (for example, the second via layer VIA2) included in the second layout LO2B has passed verification based on the feature data table FDT.

As a result, the computing system 100 may improve the reliability of a layout (for example, the second layout LO2B) generated from the integrated circuit IC.

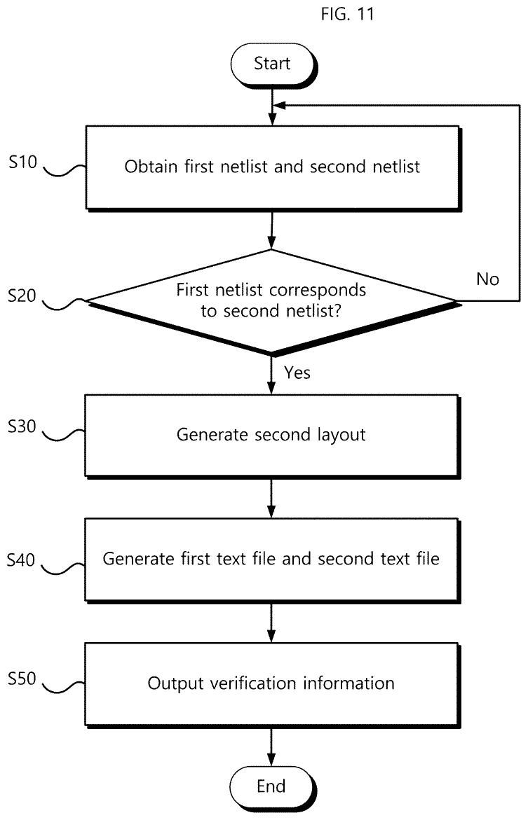

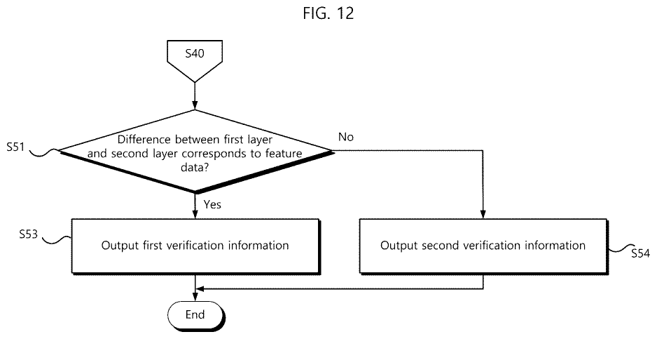

FIG. 11 is a flowchart illustrating an example of a verification method for an integrated circuit according to some implementations. FIG. 12 is a flowchart illustrating an example of a method for outputting different verification information based on a verification result according to some implementations.

Referring to FIGS. 11 and 12, a computing system 100 (or a processor 110) may verify a layout (for example, a second layout LO2) generated from an integrated circuit IC. The computing device 100 may be referred to as the computing system 100 illustrated in FIG. 1. For example, the computing system 100 may verify the second layout LO2 based on whether a difference between the second layout LO2 and a first layout LO1 corresponds to pre-stored feature data.

Referring to FIG. 11, in operation S10, the processor 110 according to one or more embodiments may obtain a first netlist NL1 and a second netlist NL2. For example, the processor 110 may obtain a first netlist NL1 corresponding to a schematic diagram SC of the integrated circuit IC. The first netlist NL1 may include parameters of each of the devices included in the schematic diagram SC and/or connection relationships between the devices.

In addition, the processor 110 may obtain a second netlist NL2 corresponding to the first layout LO1 of the integrated circuit IC. The second netlist NL2 may include parameters of each of the devices included in the first layout LO1 and/or the connection relationships between the devices.

In operation S20, the processor 110 may compare the first netlist NL1 and the second netlist NL2. For example, the processor 110 may compare the first netlist NL1 and the second netlist NL2 to determine whether the devices included in the schematic diagram SC and the first layout LO1 have corresponding parameters and connection relationships.

Accordingly, the processor 110 may compare the schematic diagram SC and the first layout LO1. For example, the processor 110 may compare the first netlist NL1 and the second netlist NL2 to determine whether the first layout LO1 and the schematic diagram SC have corresponding features.

For example, the features may include parameters (for example, length and width) of each of the devices included in the schematic diagram SC and the first layout LO1 and connection relationships between the devices, but the present disclosure is not limited thereto.

In operation S30, the processor 110 may generate the second layout LO2 when the features of the schematic diagram SC and the first layout LO1 correspond to each other. For example, the processor 110 may generate the second layout LO2 based on the first layout LO1 and a pre-input retarget rule when the features of the schematic diagram SC and the first layout LO1 correspond to each other. The processor 110 may generate the second layout LO2 by applying a retarget rule to the first layout LO1.

The retarget rule may include correction values and/or correction rules applied to each of the plurality of devices or layers included in the first layout LO1 when the second layout LO2 is generated.

For example, the retarget rule may include a first correction value applied to a first width W1 of a first layer L1 included in the first layout LO1 when the second layout LO2 is generated.

The processor 110 may generate a second layout LO2 including a second layer L2 having a second width W2, obtained by adding the first correction value to the first width W1, based on the retarget rule including the first correction value. The second layer L2 may be referred to as a layer included in the second layout LO2 corresponding to the first layer L1 included in the first layout LO1.

For example, the retarget rule may include a first correction rule for generating a second layout LO2 including a second layer L2 having a width obtained by adding the first correction value to the first width W1 of the first layer L1 from the first layout LO1.

For example, the retarget rule may include a correction rule for generating a single via layer from a plurality of via layers included in the first layout LO1 when the second layout LO2 is generated.

In operation S40, the processor 110 may generate a first text file T1 and a second text file T2. For example, the processor 110 may generate the first text file T1 from the first layout LO1. The processor 110 may generate the first text file T1 including coordinate data for each layer included in the first layout LO1. For example, the first text file T1 may include coordinate values corresponding to each vertex of the first layer L1 included in the first layout LO1.

In addition, the processor 110 may generate the second text file T2 from the second layout LO2. For example, the processor 110 may generate the second text file T2 including coordinates for each layer included in the second layout LO2. For example, the second text file T2 may include coordinate values corresponding to each vertex of the second layer L2 included in the second layout LO2.

In operation S50, the processor 110 may output verification information VI. For example, the processor 110 may output verification information VI based on a comparison result between the first text file T1 and the second text file T2 and a feature data table FDT.

The feature data table FDT may include feature data on a difference between the first layout LO1 and the second layout LO2.

For example, the feature data table FDT may include feature data indicating a difference in width between the first layer L1 of the first layout LO1 and the second layer L2 of the second layout LO2. For example, the feature data table FDT may include a correction value set for the width of the first layer L1 to generate the second layer L2.

According to some implementations, the processor 110 may compare the first text file T1 and the second text file T2 to identify differences between the layers included in the first layout LO1 and the second layout LO2. For example, the processor 110 may identify the width of the first layer L1 from the coordinate data of the first layer L1 included in the first text file T1. In addition, the processor 110 may identify the width of the second layer L2 from the coordinate data of the second layer L2 included in the second text file T2.

In addition, the processor 110 may obtain the difference between the width of the first layer L1 and the width of the second layer L2.

Referring to FIGS. 11 and 12, in operation S51, the processor 110 may determine whether the difference between the first layout LO1 and the second layout LO2 corresponds to the feature data.

Accordingly, for example, the processor 110 may determine whether the difference between the width of the first layer L1 and the width of the second layer L2 corresponds to the first correction value stored in the feature data table FDT in correspondence with the width of the first layer L1.

In operation S53, the processor 110 may output first verification information when the difference between the first layout LO1 and the second layout LO2 corresponds to the feature data in the feature data table FDT. The first verification information may include information indicating that the second layout LO2 has been generated to have a bias based on the feature data included in the feature data table FDT from the first layout LO1. For example, the first verification information may include information indicating that the second layout LO2 has passed verification based on the feature data table FDT.

In operation S54, the processor 110 may output second verification information when at least a portion of the difference between the first layout LO1 and the second layout LO2 do not correspond to the feature data in the feature data table FDT. The second verification information may include information indicating that at least some layers of the second layout LO2 have been generated to have a bias, different from the feature data included in the feature data table FDT, from the first layout LO1. For example, the second verification information may include information related to layers in the second layout LO2 that failed to pass verification based on the feature data table FDT.

Referring to the above-described configurations, a processor 110 may generate a second layout LO2 by applying a retarget rule to a first layout LO1 of an integrated circuit IC.

In addition, the processor 110 may convert the first layout LO1 and the second layout LO2 into text files T1 and T2, respectively. Furthermore, the processor 110 may identify differences between layers included in the first layout LO1 and the second layout LO2 based on coordinates included in the text files T1 and T2.

Accordingly, the computing system 100 may reduce the time required for verifying a layout (for example, the second layout LO2) generated from an integrated circuit IC.

Moreover, the processor 110 may output verification information IV based on whether the differences between layers included in the first layout LO1 and the second layout LO2 correspond to pre-stored feature data.

The verification information IV may include information on whether each layer included in the second layout LO2 has been generated to have a bias corresponding to the feature data included in a feature data table FDT from the layers included in the first layout LO1.

As a result, the computing system 100 may improve the reliability of a layout (for example, the second layout LO2) generated from an integrated circuit IC.

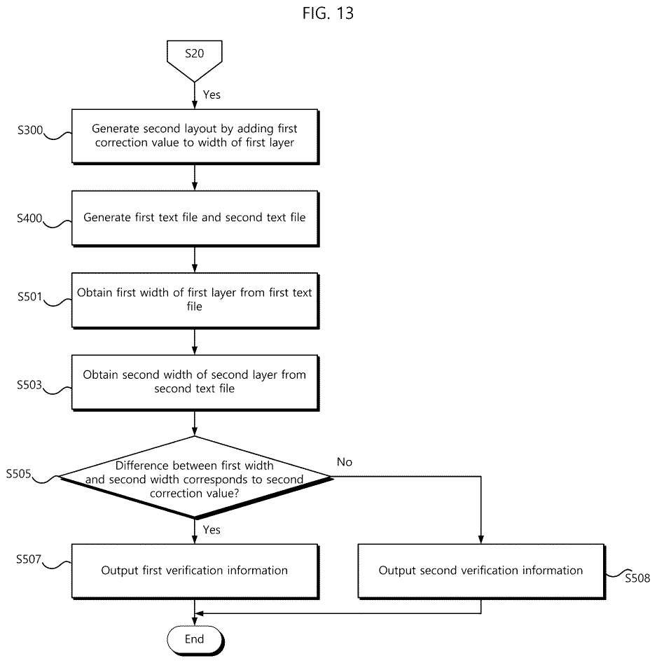

FIG. 13 is a flowchart illustrating an example of a verification method for an integrated circuit based on a difference in width between a first layer and a second layer according to some implementations.

Referring to FIG. 13, a computing system 100 (or a processor 110) may verify a second layout LO2 based on a difference in width between corresponding layers in a first layout LO1 and the second layout LO2.

In operation S300, the processor 110 may generate the second layout LO2 when features of a schematic diagram SC and the first layout LO1 correspond to each other. For example, when the features of the schematic diagram SC and the first layout LO1 correspond to each other, the processor 110 may generate the second layout LO2 based on the first layout LO1 and a pre-input retarget rule. The processor 110 may generate the second layout LO2 by applying the retarget rule to the first layout LO1.

The retarget rule may include a first correction value applied to a first width W1 of a first layer L1 included in the first layout LO1 when the second layout LO2 is generated from the first layout LO1.

For example, the retarget rule may include a first correction rule for generating the second layout LO2 including a second layer L2 having a second width W2 obtained by adding the first correction value to the first width W1 of the first layer L1 from the first layout LO1.

Accordingly, the processor 110 may generate the second layout LO2 including the second layer L2 having the second width W2, obtained by adding the first correction value to the first width W1, based on the first correction rule.

The second layer L2 may be referred to as a layer in the second layout LO2 corresponding to the first layer L1 included in the first layout LO1.

In operation S400, the processor 110 may generate a first text file T1 and a second text file T2. For example, the processor 110 may generate the first text file T1 from the first layout LO1. The first text file T1 may include first coordinate data CV1 corresponding to vertices of the first layer L1 included in the first layout LO1.

In addition, the processor 110 may generate the second text file T2 from the second layout LO2. The second text file T2 may include second coordinate data CV2 corresponding to vertices of the second layer L2 included in the second layout LO2.

In operation S501, the processor 110 may obtain a first width W1 of the first layer L1 from the first text file T1. For example, the processor 110 may obtain the first width W1 of the first layer L1 from the first coordinate data CV1 included in the first text file T1.

The processor 110 may identify the first width W1 based on the distance between a (1-1)-th coordinate CP11 and a (1-2)-th coordinate CP12 corresponding to different vertices of the first layer L1, among the first coordinate data CV1 included in the first text file T1.

In operation S503, the processor 110 may obtain a second width W2 of the second layer L2 from the second text file T2. For example, the processor 110 may obtain the second width W2 of the second layer L2 from second coordinate data CV2 included in the second text file T2.

The processor 110 may identify the second width W2 based on the distance between a first coordinate CP21 and a second coordinate CP22 corresponding to different vertices of the second layer L2, among the second coordinate data CV2 included in the second text file T2.

The order of performing operations S501 and S503 is not limited to that illustrated in FIG. 13. According to some implementations, at least a portion of operations S501 and S503 may be performed simultaneously. According to some implementations, operation S503 may be performed before operation S501.

In operation S505, the processor 110 may determine whether the difference between the first width W1 and the second width W2 corresponds to a second correction value CA. For example, the processor 110 may determine whether the difference between the first width W1 and the second width W2 corresponds to the second correction value CA stored in a feature data table FDT for corresponding layers of the first layout LO1 and the second layout LO2.

For example, the processor 110 may determine whether the difference between the first width W1 and the second width W2 matches the second correction value CA stored for a layer corresponding to a gate electrode of an NMOS transistor in each of the first layout LO1 and the second layout LO2.

In operation S507, the processor 110 may output first verification information when the difference between the first layout LO1 and the second layout LO2 corresponds to the feature data in the feature data table FDT. For example, the processor 110 may output the first verification information when the difference between the first width W1 and the second width W2 is determined to be 9 nm and the second correction value CA stored in the feature data table FDT for a layer corresponding to the gate electrode of an NMOS transistor is 9 nm.

The first verification information may include information indicating that the second layout LO2 has been generated to have a bias based on the feature data included in the feature data table FDT from the first layout LO1. For example, the first verification information may include information indicating that the second layout LO2 has passed verification based on the feature data table FDT.

In operation S508, the processor 110 may output second verification information when at least a portion of the difference between the first layout LO1 and the second layout LO2 does not correspond to the feature data in the feature data table FDT. For example, the processor 110 may output the second verification information when the difference between the first width W1 and the second width W2 does not correspond to the second correction value CA stored in the feature data table FDT for the layer corresponding to the gate electrode of the NMOS transistor.

The second verification information may include information indicating that at least some layers of the second layout LO2 have been generated to have a bias, different from the feature data included in the feature data table FDT, from the first layout LO1. For example, the second verification information may include information related to layers in the second layout LO2 that failed to pass verification based on the feature data table FDT.

Referring to the above-described configurations, the processor 110 may generate the second layout LO2 by applying a retarget rule to the first layout LO1 of the integrated circuit IC.

In addition, the processor 110 may convert the first layout LO1 and the second layout LO2 into text files T1 and T2, respectively. Furthermore, the processor 110 may identify differences in parameters (for example, width) between the layers L1 and L2 included in the first layout LO1 and the second layout LO2 based on coordinate data included in the text files T1 and T2.

Accordingly, the computing system 100 may reduce the time required for verifying a layout (for example, second layout LO2) generated from the integrated circuit IC.

In addition, the processor 110 may output verification information IV based on whether the differences between layers L1 and L2 included in the first layout LO1 and the second layout LO2 correspond to pre-stored feature data.

The verification information IV may include information on whether each layer (for example, second layer L2) included in the second layout LO2 has been generated to have a bias corresponding to the feature data included in a feature data table FDT from the layers (for example, the first layer L1) included in the first layout LO1.

Accordingly, the computing system 100 may improve the reliability of a layout (for example, second layout LO2) generated from the integrated circuit IC.

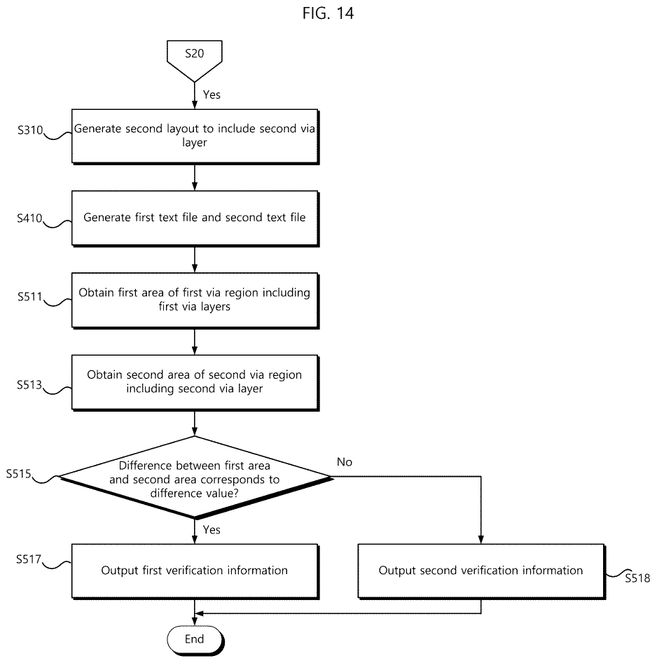

FIG. 14 is a flowchart illustrating an example of a verification method for an integrated circuit based on an area difference between via layers of a first layout and a second layout according to some implementations.

Referring to FIG. 14, a computing system 100 (or a processor 110) may verify a second layout LO2 based on a difference in area between corresponding via layers in a first layout LO1 and the second layout LO2.

In operation S310, the processor 110 may generate the second layout LO2 to include a second via layer VIA2. For example, when the features of a schematic diagram SC and the first layout LO1 correspond to each other, the processor 110 may generate the second layout LO2 including the second via layer VIA2 based on the first layout LO1 and a pre-input retarget rule.

The first layout LO1 may include at least two first via layers VIA11 and VIA12 disposed near each other. In addition, each of the first via layer VIA11 and the second via layer VIA12 may have an area less than a predetermined threshold. For example, the first via layer VIA11 and the second via layer VIA12 may each have a smaller area than a predetermined threshold value and be spaced at a distance less than or equal to threshold distance from each other.

Accordingly, the retarget rule may include a second correction rule for generating the second layout LO2 including a second via layer VIA2 having an area equal to the sum of areas of the first via layers VIA11 and VIA12 from the first layout LO1.

Accordingly, the processor 110 may generate the second layout LO2 including the second via layer VIA2 having an area equal to the sum of the areas of the first via layers VIA11 and VIA12, based on the second correction rule.

In operation S410, the processor 110 may generate a first text file T1 and a second text file T2. For example, the processor 110 may generate the first text file T1 from the first layout LO1. The first text file T1 may include coordinate data corresponding to vertices of a first via region VA1 including the first via layers VIA11 and VIA12.

In addition, the processor 110 may generate the second text file T2 from the second layout LO2. The second text file T2 may include coordinate data corresponding to vertices of a second via region VA2 including the second via layer VIA2.

In operation S511, the processor 110 may obtain a first area of the first via region VA1 including the first via layers VIA11 and VIA12. For example, the processor 110 may determine the first area of the first via region VA1 from the coordinate data corresponding to the vertices of the first via region VA1 in the first text file T1.

In operation S513, the processor 110 may obtain a second area of the second via region VA2 including the second via layer VIA2. For example, the processor 110 may determine the second area of the second via region VA2 from the coordinate data corresponding to the vertices of the second via region VA2 in the second text file T2.

In operation S515, the processor 110 may determine whether a difference in area between the first via region VA1 and the second via region VA2 corresponds to a difference value. For example, the processor 110 may compare the first area of the first via region VA1 including the first via layers VIA11 and VIA12 and the second area of the second via region VA2 including the second via layer VIA2.

Furthermore, the processor 110 may determine whether the difference between the first area of the first via region VA1 and the second area of the second via region VA2 corresponds to a difference value for areas of via regions stored in a feature data table FDT.

The feature data table FDT may include a difference value in area between via layers disposed in corresponding regions in the first layout LO1 and the second layout LO2.

For example, the processor 110 may determine whether the difference between the first area of the first via region VA1 and the second area of the second via region VA2 matches the difference value stored in the feature data table FDT corresponding to via layers.

In addition, the processor 110 may output verification information VI based on a difference between the first layout LO1 and the second layout LO2 identified from the first text file T1 and the second text file T2, and the feature data table FDT.

In operation S517, the processor 110 may output first verification information when the difference between the first layout LO1 and the second layout LO2 corresponds to the feature data in the feature data table FDT. For example, the processor 110 may output the first verification information when the difference between the first area of the first via region VA1 and the second area of the second via layer VIA2 corresponds to the difference value stored for the via layers of the first layout LO1 and the second layout LO2.

For example, the processor 110 may output the first verification information when a first area of the first via region VA1 is “1240 nm²,” a second area of the second via region VA2 is “1232 nm²,” and the difference value stored in the feature data table FDT is “8 nm².”

The first verification information may include information indicating that the second layout LO2 has been generated to have a bias based on the feature data included in the feature data table FDT from the first layout LO1. For example, the first verification information may include information indicating that the second layout LO2 has passed verification based on the feature data table FDT.

In operation S518, the processor 110 may output second verification information when at least a portion of the difference between the first layout LO1 and the second layout LO2 does not correspond to the feature data in the feature data table FDT. For example, the processor 110 may output the second verification information when the difference between the first area of the first via region VA1 and the second area of the second via layer VIA2 does not correspond to the difference value stored for the via layers of the first layout LO1 and the second layout LO2.

For example, the processor 110 may output the second verification information when a first area of the first via region VA1 is “1240 nm²,” a second area of the second via region VA2 is “1239 nm²,” and the difference value stored in the feature data table FDT is “8 nm².”

The second verification information may include information indicating that at least some layers (for example, the second via layer VIA2) of the second layout LO2 have been generated to have a bias, different from the feature data included in the feature data table FDT, from the first layout LO1. For example, the second verification information may include information related to layers in the second layout LO2 that failed to pass verification based on the feature data table FDT.

Referring to the above-described configurations, the processor 110 may generate the second layout LO2 by applying a retarget rule to the first layout LO1 of the integrated circuit IC.

In addition, the processor 110 may convert the first layout LO1 and the second layout LO2 into text files T1 and T2, respectively. Furthermore, the processor 110 may identify differences in parameters (for example, area) between via layers VIA11, VIA12, and VIA2 included in the first layout LO1 and the second layout LO2, based on coordinates included in the text files T1 and T2.

Accordingly, the computing system 100 may reduce the time required for verifying a layout (for example, the second layout LO2) generated from the integrated circuit IC.

In addition, the processor 110 may output verification information IV based on whether the differences between via layers VIA11, VIA12, and VIA2 included in the first layout LO1 and the second layout LO2 correspond to pre-stored feature data. The verification information IV may include information on whether each layer (for example, the second via layer VIA2) included in the second layout LO2 has passed verification based on the feature data table FDT.

As a result, the computing system 100 may improve the reliability of a layout (for example, the second layout LO2) generated from the integrated circuit IC.

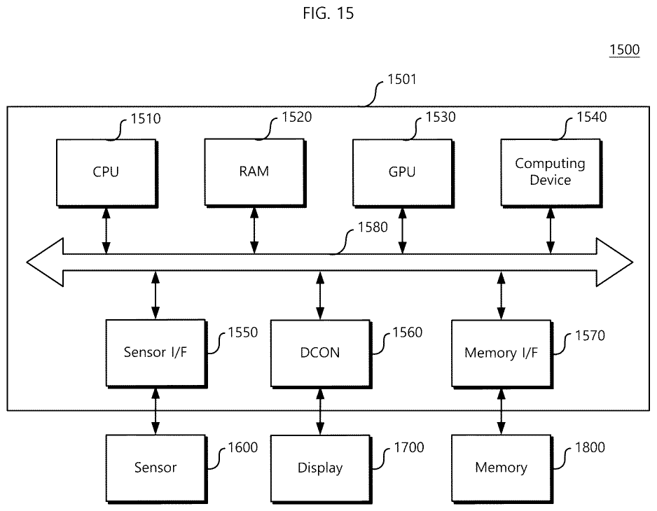

FIG. 15 is a block diagram illustrating an example of an integrated circuit and an electronic device including the same according to some implementations.

Referring to FIG. 15, an electronic device 1500 may include an integrated circuit 1501 and a sensor 1600, a display 1700, and a memory 1800 connected to the integrated circuit 1501. For example, the electronic device 1500 may be referred to as a mobile device, such as a smartphone, a gaming device, an advanced driver assistance system (ADAS), a wearable device, or a data server.

According to some implementations, the integrated circuit 1501 may include a central processing unit (CPU) 1510, a random access memory (RAM) 1520, a graphics processing unit (GPU) 1530, a computing device 1540, a sensor interface 1550, a display controller 1560, and a memory interface 1570. The integrated circuit 1501 may further include other general-purpose components such as a communication module, a digital signal processor (DSP), or a video module. The components of the integrated circuit 1501 (the CPU 1510, the RAM 1520, the GPU 1530, the computing device 1540, the sensor interface 1550, the display controller 1560, and the memory interface 1570) may transmit and receive data to and from each other via a bus 1580.

The integrated circuit 1501 according to some implementations may be an application processor. In addition, the integrated circuit 1501 according to some implementations may be implemented as a system-on-chip (SoC).

The CPU 1510 may control the overall operation of the integrated circuit 1501. The CPU 1510 may include a single core or multiple cores. The CPU 1510 may process or execute programs and/or data stored in the memory 1800.

According to some implementations, the CPU 1510 may control the computing device 1540 to execute programs stored in the memory 1800, thereby performing the verification method according to some implementations. The computing device 1540 may be understood as having substantially the same configuration as the computing system 100 illustrated in FIG. 1.

For example, the computing device 1540 may generate the second layout LO2 by applying a retarget rule to a first layout LO1 of the integrated circuit 1501 in response to a schematic diagram SC of the integrated circuit 1501 corresponding to the first layout LO1.

In addition, the computing device 1540 may convert the first layout LO1 and a second layout LO2 into text files T1 and T2, respectively. Furthermore, the computing device 1540 may identify differences between layers included in the first layout LO1 and the second layout LO2 based on coordinates included in the text files T1 and T2.

Thus, the computing device 1540 may reduce the time required for verifying a layout (for example, the second layout LO2) generated from the integrated circuit IC.

In addition, the computing device 1540 may output verification information IV based on whether the differences between layers included in the first layout LO1 and the second layout LO2 correspond to pre-stored feature data.

The verification information IV may include information on whether each layer included in the second layout LO2 has been generated to have a bias corresponding to the feature data included in a feature data table FDT from the layers included in the first layout LO1.

As a result, the computing device 1540 may improve the reliability of a layout (for example, the second layout LO2) generated from the integrated circuit IC.

The RAM 1520 may temporarily store programs, data, and/or instructions. According to some implementations, the RAM 1520 may be implemented as a DRAM or an SRAM. The RAM 1520 may temporarily store data input/output through interfaces 1550 and 1570 or data generated by the GPU 1530 or CPU 1510, such as image data. According to some implementations, the integrated circuit 1501 may further include a read-only memory (ROM). The ROM may store programs and/or data that are continuously used. The ROM may be implemented as an erasable programmable ROM (EPROM) or an electrically erasable programmable ROM (EEPROM).

The GPU 1530 may perform image processing on image data. For example, the GPU 1530 may perform image processing on image data received through the sensor interface 1550. The image data processed by the GPU 1530 may be stored in the memory 1800 or provided to the display 1700 through the display controller 1560.

The sensor interface 1550 may receive data (for example, image data, audio data, or the like) input from the sensor 1600 connected to the integrated circuit 1501.

The display controller 1560 may output data (for example, images) to the display 1700. The display 1700 may output image data or video data through a display such as a liquid-crystal display (LCD) or an active matrix organic light emitting diode (AMOLED).

For example, the CPU 1510 (or the computing device 1540) may output a display image DI, included in the second verification information, through the display 1700. The display image DI may be referred to as an image with highlighted regions, generated within the second layout LO2 to have a different bias from feature data included in the feature data table FDT, from the first layout LO1.

The memory interface 1570 may interface data input from or output to the memory 1800 external to the integrated circuit 1501. According to some implementations, the memory 1800 may be implemented as a volatile memory such as a DRAM or an SRAM, or a non-volatile memory, such as an ReRAM, a PRAM, or a NAND flash memory. The memory 1800 may also be implemented as a memory card (a multimedia card (MMC), an embedded multimedia card (eMMC), a secure digital (SD) card, or a micro-SD card), or the like

As described above, the processor 110 may generate the second layout LO2 by applying a retarget rule to the first layout LO1 of the integrated circuit IC.

In addition, the processor 110 may convert the first layout LO1 and the second layout LO2 into text files T1 and T2, respectively. Furthermore, the processor 110 may identify differences between layers included in the first layout LO1 and the second layout LO2, based on coordinates included in the text files T1 and T2.

Accordingly, the computing device 100 may reduce the time required for verifying a layout (for example, the second layout LO2) generated from the integrated circuit IC.

Moreover, the processor 110 may output verification information IV based on whether the differences between layers included in the first layout LO1 and the second layout LO2 correspond to pre-stored feature data.

The verification information IV may include information on whether each layer included in the second layout LO2 has been generated to have a bias corresponding to the feature data included in a feature data table FDT from the layers included in the first layout LO1.

As a result, the computing device 100 may improve the reliability of a layout (for example, second layout LO2) generated from an integrated circuit IC.

As set forth above, the verification method according to some implementations may improve the reliability of a layout generated from integrated circuits.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A verification method for a layout of an integrated circuit performed by a computer device, the verification method comprising:
comparing a first netlist corresponding to a schematic diagram of the integrated circuit and a second netlist corresponding to a first layout of the integrated circuit;
generating a second layout by applying a pre-input retarget rule to the first layout in response to determining that the first netlist and the second netlist correspond to each other;
generating a first text file, comprising coordinate data for each of layers included in the first layout, from the first layout;
generating a second text file, comprising coordinate data for each of layers included in the second layout, from the second layout; and
outputting verification information indicating whether a difference between the first layout and the second layout corresponds to pre-stored feature data, based on the first text file and the second text file.

2. The verification method of claim 1, wherein the outputting of the verification information comprises:
outputting first verification information based on the difference between the first layout and the second layout corresponding to the pre-stored feature data; or
outputting second verification information based on the difference between the first layout and the second layout failing to correspond to the pre-stored feature data.

3. The verification method of claim 2,
wherein the pre-input retarget rule comprises a first correction rule for adding a first correction value to a width of a first layer included in the first layout; and
wherein the generating of the second layout comprises including a second layer having a second width in the second layer, wherein the second width is obtained by adding the first correction value to a first width of the first layer, based on the first correction rule.

4. The verification method of claim 3,
wherein the pre-stored feature data comprises a second correction value set for the width of the first layer; and
wherein the outputting of the first verification information comprises:
obtaining the first width of the first layer on the first layout based on first coordinate data corresponding to the first layer in the first text file;
obtaining the second width of the second layer on the second layout based on second coordinate data corresponding to the second layer in the second text file; and
outputting the first verification information based on a difference between the first width and the second width corresponding to the second correction value.

5. The verification method of claim 4,
wherein the first coordinate data comprises a plurality of first coordinates, respectively corresponding to vertices of the first layer; and
wherein the obtaining of the first width comprises obtaining the first width based on a distance between a first coordinate of the plurality of first coordinates and a second coordinate of the plurality of first coordinates.

6. The verification method of claim 2,
wherein the pre-input retarget rule comprises a second correction rule for generating a second via layer having an area equal to a sum of areas of at least two first via layers based on the first layout comprising the at least two first via layers, each first via layer of the at least two first via layers having a smaller area than a threshold value and disposed near each other; and
wherein the generating of the second layout comprises including the second via layer in the second layout, wherein the second via layer has an area equal to the sum of the areas of the first via layers, based on the second correction rule.

7. The verification method of claim 6,
wherein the pre-stored feature data comprises a difference value between an area of a first via region comprising the first via layers and an area of a second via region comprising the second via layer; and
wherein the outputting of the first verification information comprises:
obtaining a first area of the first via region on the first layout based on coordinate values corresponding to the first via layers included in the first text file;
obtaining a second area of the second via region on the second layout based on coordinate values corresponding to the second via layer included in the second text file; and
outputting the first verification information based on a difference between the first area and the second area corresponding to the difference value.

8. The verification method of claim 1, wherein the comparing of the first netlist and the second netlist comprises:
obtaining a width of a first element, included in the schematic diagram, from the first netlist;
obtaining a width of a second element, included in the first layout and corresponding to the first element, from the second netlist; and
determining that the first netlist and the second netlist correspond to each other based on the width of the first element matching the width of the second element.

9. The verification method of claim 4, wherein the outputting of the second verification information comprises:
outputting a display image highlighted within a difference region corresponding to a difference between the first correction value and the second correction value within the second layer, on the second layout based on the difference between the first width and the second width failing to correspond to the second correction value.

10. The verification method of claim 1, comprising:
obtaining the first netlist corresponding to the schematic diagram of the integrated circuit; and
obtaining the second netlist corresponding to the first layout of the integrated circuit.

11. A computing system comprising:
at least one processor; and
a memory configured to store instructions that, when executed, cause the at least one processor to perform a verification method for an integrated circuit,
wherein the verification method comprises:
comparing a first netlist corresponding to a schematic diagram of the integrated circuit and a second netlist corresponding to a first layout of the integrated circuit;
generating a second layout by applying a pre-input retarget rule to the first layout in response to determining that the first netlist and the second netlist correspond to each other;
generating a first text file, comprising coordinate data for each of layers included in the first layout, from the first layout;
generating a second text file, comprising coordinate data for each of layers included in the second layout, from the second layout; and
outputting first verification information indicating whether a difference between the first layout and the second layout corresponds to pre-stored feature data, based on the first text file and the second text file.

12. The computing system of claim 11,
wherein the pre-input retarget rule comprises a first correction rule for adding a first correction value to a width of a first layer included in the first layout; and
wherein the generating of the second layout comprises including a second layer in the second layout, wherein the second layout has a second width obtained by adding the first correction value to a first width of the first layer, based on the first correction rule.

13. The computing system of claim 12,
wherein the pre-stored feature data comprises a second correction value preset for the width of the first layer; and
wherein the outputting of the first verification information comprises:
obtaining the first width of the first layer on the first layout based on first coordinate data corresponding to the first layer in the first text file;
obtaining the second width of the second layer on the second layout based on second coordinate data corresponding to the second layer in the second text file; and
outputting the first verification information based on a difference between the first width and the second width corresponding to the second correction value.

14. The computing system of claim 12,
wherein the pre-input retarget rule comprises a second correction rule for generating a second via layer having an area equal to a sum of areas of at least two first via layers based on the first layout comprising the at least two first via layers, each first via layer of the at least two first via layers having a smaller area than a threshold value and disposed near each other; and
wherein the generating of the second layout comprises including the the second via layer in the second layout, wherein the second via layer has an area equal to the sum of the areas of the first via layers, based on the second correction rule.

15. The computing system of claim 14,
wherein the pre-stored feature data comprises a difference value between an area of a first via region comprising the first via layers and an area of a second via region comprising the second via layer; and
wherein the outputting of the first verification information comprises:
obtaining an area of a first via region comprising the first via layers on the first layout based on coordinate values of the first via layers included in the first text file;
obtaining an area of a second via layer on the second layout based on a coordinate value of the second via layer included in the second text file; and
outputting the first verification information based on a difference between an area of a region including the first via layers and an area of the second via layer corresponding to the difference value.

16. The computing system of claim 13, comprising:
outputting second verification information based on a difference between the first layer and the second layer failing to correspond to the pre-stored feature data, based on the first coordinate data and the second coordinate data; and
wherein the outputting of the second verification information comprises outputting a display image highlighted within a region corresponding to a difference between the first layer and the second layer, on the second layout.

17. A verification method for a layout of an integrated circuit performed by a computer device, the verification method comprising:
obtaining a first netlist corresponding to a schematic diagram of the integrated circuit;
obtaining a second netlist corresponding to a first layout of the integrated circuit;
comparing the first netlist and the second netlist to determine that elements included in the schematic diagram correspond to elements included in the first layout;
generating a second layout by applying a retarget rule to the first layout based on determining that the elements included in the schematic diagram correspond to the elements included in the first layout;
generating a first text file corresponding to the first layout;
generating a second text file corresponding to the second layout; and
comparing the first text file and the second text file to output verification information indicating whether a difference between the first layout and the second layout corresponds to pre-stored feature data.

18. The verification method of claim 17, wherein the outputting of the verification information comprises:
outputting first verification information based on the difference between the first layout and the second layout corresponding to the pre-stored feature data; and
outputting second verification information based on the difference between the first layout and the second layout fails to correspond to the pre-stored feature data.

19. The verification method of claim 18,
wherein the first text file comprises first coordinate data of a first layer included in the first layout;
wherein the second text file comprises second coordinate data of a second layer included in the second layout;
wherein the retarget rule comprises a first correction rule for adding a first correction value to a width of the first layer; and
wherein the generating of the second layout comprises including the second layer in the second layout, wherein the second layer has a second width obtained by adding the first correction value to a first width of the first layer, based on the first correction rule.

20. The verification method of claim 19,
wherein the pre-stored feature data comprises a second correction value preset for the width of the first layer; and
wherein the outputting of the first verification information comprises:
obtaining the first width of the first layer on the first layout based on the first coordinate data included in the first text file;
obtaining the second width of the second layer on the second layout based on the second coordinate data included in the second text file; and
outputting the first verification information based on a difference between the first width and the second width corresponding to the second correction value.
